(19) United States
(12) Patent Application Publication
(10) Pub. No.: US 2024/0147612 A1
(43) Pub. Date: May 2, 2024

(54) PRINTED WIRING BOARD

(71) Applicant: SUMITOMO ELECTRIC INDUSTRIES, LTD., Osaka (JP)

(72) Inventors: Kenji TAKAHASHI, Osaka (JP); Shoichiro SAKAI, Osaka (JP)

(73) Assignee: SUMITOMO ELECTRIC INDUSTRIES, LTD., Osaka (JP)

(21) Appl. No.: 18/278,253

(22) PCT Filed: Jul. 8, 2022
(86) PCT No.: PCT/JP2022/027124

§ 371 Date: Aug. 22, 2023

(30) Foreign Application Priority Data
Jul. 9, 2021 (JP) 2021-114335

(51) Int. Cl. H05K 1/02

(52) U.S. Cl. CPC H05K 1/0298; H05K 2201/0352; H05K 2201/095

(57) ABSTRACT

A printed wiring board includes a base and a conductor layer. A through hole reaching the second surface from the first surface is formed in the base. A first opening of the through hole is formed in the first surface of the base. A second opening of the through hole is formed in the second surface of the base. A conductor layer is disposed inside the through hole. The base includes a first protrusion. The first protrusion protrudes from an edge portion of the first opening. The first opening has a first opening width in a first cross section passing through the first protrusion and a center of the first opening and taken along a thickness direction of the base. The second opening has a second opening width in the first cross section. The first opening width is smaller than the second opening width.

### TECHNICAL FIELD

The present disclosure relates to a printed wiring board. This application claims priority based on Japanese Patent Application No. 2021-114335 filed on Jul. 9, 2021. The entire contents described in the Japanese Patent Application are incorporated herein by reference.

### BACKGROUND

Conventionally, there is known a printed wiring board in which conductor layers are formed on a front surface and a back surface of a base (see, for example, Japanese Unexamined Patent Application Publication No. 2019-197750).

### PRIOR ART DOCUMENT

### Patent Literature

PTL 1. Japanese Unexamined Patent Application Publication No. 2019-197750

### SUMMARY

A printed wiring board of the present disclosure includes a base and a conductor layer. The base has a first surface and a second surface positioned opposite to the first surface. A through hole reaching the second surface from the first surface is formed in the base. A first opening being an open end of the through hole is formed in the first surface of the base. A second opening being an open end of the through hole is formed in the second surface of the base. The conductor layer is disposed at least inside the through hole. The base includes a first protrusion. The first protrusion protrudes from an edge portion of the first opening. The first opening has a first opening width in a first cross section passing through the first protrusion and a center of the first opening and taken along a thickness direction of the base. The second opening has a second opening width in the first cross section. The first opening width is smaller than the second opening width.

### BRIEF DESCRIPTION OF THE DRAWINGS

FIG. 1 is a partial cross-sectional schematic view of a printed wiring board according to a first embodiment.

FIG. 2 is a partially enlarged cross-sectional schematic view of the printed wiring board shown in FIG. 1.

FIG. 3 is a schematic cross-sectional view for explaining a method of manufacturing the printed wiring board shown in FIG. 1.

FIG. 4 is a schematic cross-sectional view for explaining a method of manufacturing the printed wiring board shown in FIG. 1.

FIG. 5 is a cross-sectional schematic view for explaining a method of manufacturing the printed wiring board shown in FIG. 1.

FIG. 6 is a cross-sectional schematic view for explaining a method of manufacturing the printed wiring board shown in FIG. 1.

FIG. 7 is a partial cross-sectional schematic diagram showing a first modification of the printed wiring board shown in FIG. 1.

FIG. 8 is a partial cross-sectional schematic diagram showing a second modification of the printed wiring board shown in FIG. 1.

FIG. 9 is a partially enlarged cross-sectional schematic view of the printed wiring board shown in FIG. 8.

FIG. 10 is a partial cross-sectional schematic view showing a third modification of the printed wiring board shown in FIG. 1.

FIG. 11 is a partial cross-sectional schematic view of a printed wiring board according to a second embodiment.

FIG. 12 is a partial cross-sectional schematic diagram showing a first modification of the printed wiring board shown in FIG. 11.

### DETAILED DESCRIPTION

### Problem to be Solved by the Present Disclosure

In the printed wiring board, a through hole is formed in the base. The through hole is filled with a portion of a conductor layer. The conductor layer on the front surface side of the base and the conductor layer on the back surface side of the base are electrically connected by a portion of a conductor layer filled in the through hole. In the conventional printed wiring board described above, in order to suppress the occurrence of voids in the conductor layer inside the through hole, the width of the through hole gradually decreases from the front surface side to the back surface side of the base.

However, in the above-described printed wiring board, since the cross-sectional area of the conductor layer disposed inside the through hole becomes smaller toward the back surface side, it is necessary to increase the size of the through hole to some extent in order to obtain sufficient conductive characteristics. As a result, it has been difficult to miniaturize the through hole while suppressing the occurrence of voids in the conductor layer inside the through hole.

Therefore, an object of the present disclosure is to provide a printed wiring board capable of miniaturizing a through hole while suppressing the occurrence of a void inside the through hole.

### Effects of Present Disclosure

According to the present disclosure, it is possible to obtain a printed wiring board capable of miniaturizing a through hole while suppressing the occurrence of a void inside the through hole.

### DESCRIPTION OF EMBODIMENTS OF PRESENT DISCLOSURE

First, embodiments of the present disclosure will be listed and explained.
(1) A printed wiring board of the present disclosure includes a base and a conductor layer. The base has a first surface and a second surface positioned opposite to the first surface. A through hole reaching the second surface from the first surface is formed in the base. A first opening being an open end of the through hole is formed in the first surface of the base. A second opening being an open end of the through hole is formed in the second surface of the base. The conductor layer is disposed at least inside the through hole. The base includes a first protrusion. The first protrusion protrudes from an edge portion of the first opening. The first opening has a first opening width in a first cross section passing through the first protrusion and a center of the first opening and taken along a thickness direction of the base. The second opening has a second opening width in the first cross section. The first opening width is smaller than the second opening width.

In this case, since the first protrusion is formed at the edge portion of the first opening, the first opening width may be smaller than the second opening width without largely changing the width of the through hole. Therefore, when the conductor layer is formed inside the through hole, the conductor layer can be formed so as to close the through hole on the first opening side. Thereafter, the conductor layer may be formed from the first opening side to the second opening side in the through hole. Therefore, it is possible to suppress the occurrence of voids by closing the first opening side and the second opening side before the inside of the through hole is filled with the conductor layer.

Further, since the first opening width is adjusted by forming the first protrusion, there is no need for a structure in which the inner wall itself of the through hole is inclined with respect to the first surface as in the case where the side wall of the through hole is inclined to make the first opening width narrower than the second opening width. Therefore, the problem that the width of the second opening becomes excessively larger than that of the first opening due to the inclination of the inner wall of the through hole with respect to the first surface does not occur. Therefore, by making the width of the second opening on the second surface smaller than that in the related art, the region occupied by the through hole can be made smaller than that in the related art. As a result, it is possible to realize a printed wiring board in which the occurrence of voids is suppressed and through holes are made fine.
(2) In the printed wiring board according to (1), in the first cross section, an inner wall of the through hole may be inclined with respect to the first surface such that a width of the through hole increases toward the second opening from the first opening. In this case, the occurrence of voids inside the through hole can be further suppressed. Since the first opening width is adjusted by the first protrusion, the effect of suppressing the occurrence of voids can be obtained even if the inclination angle of the inner wall of the through hole is minimized.
(3) In the printed wiring board according to (1) or (2), the first protrusion may include a first conductor layer including a material differing from a material of the conductor layer. In this case, since the first protrusion can have conductivity, the conductor layer can be easily formed on the surface of the first protrusion by using an electroplating method.
(4) In the printed wiring board according to (3), the first conductor layer may extend to a region adjacent to the first opening at the first surface of the base. In this case, the conductor layer can be easily formed to reach the first surface of the base by the electroplating method.
(5) In the printed wiring board according to (3) or (4), the material of the first conductor layer may include nickel (Ni) or chromium (Cr). The material of the conductor layer may include, for example, copper (Cu). In this case, the first conductor layer can be used as an underlying material for forming the conductor layer. Therefore, the conductor layer can be easily formed so as to cover the first protrusion.
(6) In the printed wiring board of any one of (3) to (5), the base may include a second protrusion protruding from an edge portion of the second opening. The second protrusion may include a second conductor layer including a material differing from the material of the conductor layer. A width of the second opening at a second cross section passing through the second protrusion and a center of the second opening may be greater than a first opening width. Also in this case, since the conductor layer can be formed from the first opening side, the occurrence of voids inside the through hole can be suppressed.
(7) In the printed wiring board according to (6), the second conductor layer may extend to a region adjacent to the second opening at the second surface of the base. In this case, the conductor layer can be easily formed to reach the second surface of the base by the electroplating method.
(8) In the printed wiring board according to (6) or (7), the material of the second conductor layer may include nickel (Ni) or chromium (Cr). In this case, the second conductor layer can be used as an underlying material for forming the conductor layer. Therefore, the conductor layer can be easily formed so as to cover the second protrusion.
(9) In the printed wiring board according to any one of (1) to (8), the first protrusion may extend in a direction along the first surface. In this case, the first opening width can be reliably reduced by the first protrusion.
(10) In the printed wiring board according to any one of (1) to (8), the first protrusion may extend in a direction crossing the first surface. Also in this case, since the first protrusion protrudes from the edge portion of the first opening, the first opening width can be reduced by the first protrusion.
(11) In the printed wiring board according to any one of (1) to (10), a protrusion length of the first protrusion in a first radial direction toward the center of the first opening from the first protrusion may be 0.1 μm to 5 μm. In this case, when the conductor layer is formed inside the through hole, the first opening side can be closed by the conductor layer before the second opening side.
(12) In the printed wiring board according to (11), the protrusion length of the first protrusion may be 0.1% to 10% of the first opening width. Also in this case, when the conductor layer is formed inside the through hole, the first opening side can be closed by the conductor layer before the second opening side.
(13) In the printed wiring board according to any one of (1) to (12), a protrusion height of the first protrusion in a direction perpendicular to the first surface may be 0.01 μm to 1 μm. In this case, the conductor layer can be easily formed to cover the first protrusion.
(14) In the printed wiring board according to (13), the protrusion height of the first protrusion may be 0.01% to 10% of a thickness of the base. In this case, the conductor layer can be easily formed to cover the first protrusion.

### DETAILS OF EMBODIMENTS OF THE PRESENT DISCLOSURE

The details of embodiments of the present disclosure are set forth below. In the following description, identical or corresponding elements are provided with the same reference signs and will not be described repeatedly.

### First Embodiment

### <Configuration of Printed Wiring Board>

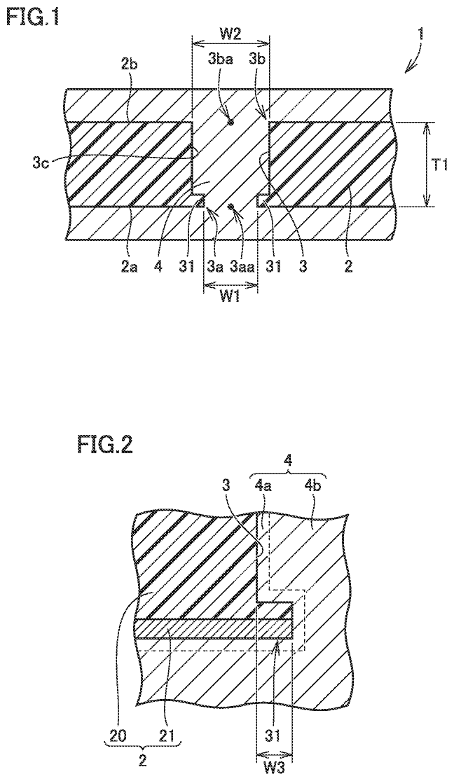

FIG. 1 is a partial cross-sectional schematic view of a printed wiring board according to a first embodiment. FIG. 2 is a partially enlarged cross-sectional schematic view of the printed wiring board shown in FIG. 1.

As shown in FIGS. 1 and 2, a printed wiring board 1 includes a base 2 and a conductor layer 4. Base 2 includes a first surface 2a and a second surface 2b positioned opposite to first surface 2a. A through hole 3 reaching second surface 2b from first surface 2a is formed in base 2. That is, base 2 has through hole 3.

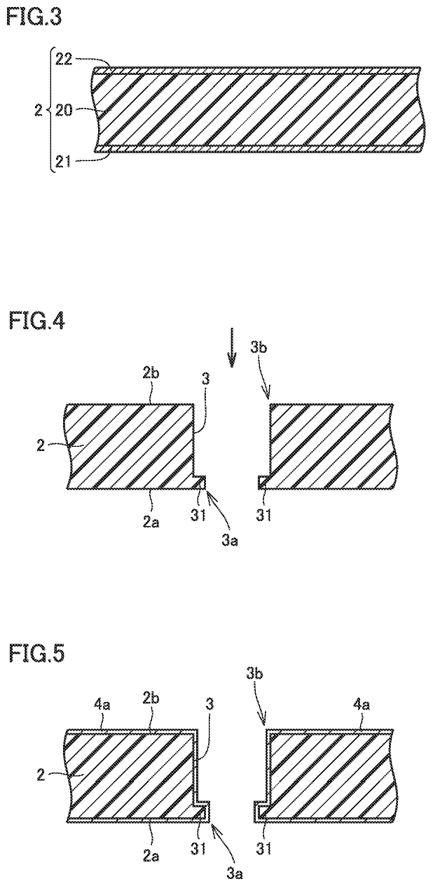

As shown in FIG. 3, base 2 is a stacking body of a base film 20, a first conductor layer 21, and a second conductor layer 22. First conductor layer 21 is formed on the lower surface of base 2. Second conductor layer 22 is formed on the upper surface of base 2. That is, base 2 is a stacking body in which first conductor layer 21, base film 20, and second conductor layer 22 are stacked in order. Base film 20 is made of an insulator and is a plate-like or sheet-like member. As the material of base film 20, any material can be used, and for example, a resin such as polyimide can be used. First conductor layer 21 and second conductor layer 22 have a material different from that of conductor layer 4. For example, when conductor layer 4 is made of copper (Cu) or a copper alloy, first conductor layer 21 and second conductor layer 22 include nickel (Ni) or chromium (Cr). First conductor layer 21 and second conductor layer 22 may include an alloy of nickel and chromium.

A first opening 3a being an open end of through hole 3 is formed on first surface 2a of base 2. That is, first surface 2a of base 2 has first opening 3a. A second opening 3b being an open end of through hole 3 is formed on second surface 2b of base 2. That is, second surface 2b of base 2 has second opening 3b. The planar shape of each of first opening 3a and second opening 3b may be any shape such as a circular shape, an elliptical shape, or a quadrangular shape. Conductor layer 4 is formed so as to extend from the inside of through hole 3 onto first surface 2a and second surface 2b.

Base 2 includes a first protrusion 31. First protrusion 31 protrudes from an edge portion of first opening 3a. First protrusion 31 is formed on the two edge portions facing first opening 3a as shown in FIG. 1. First protrusion 31 may be formed on the entire circumference of the edge portion of first opening 3a. Alternatively, first protrusion 31 may be formed on only a part of the edge portion of first opening 3a. Here, the edge portion of first opening 3a is a portion of base 2 that surrounds an annular line from the outer peripheral side and is adjacent to the annular line, when the annular line is assumed as a line at which first surface 2a intersects a virtual plane obtained by extending an inner wall 3c toward first surface 2a in first opening 3a.

First protrusion 31 is formed so as to extend in a direction along first surface 2a. First protrusion 31 is formed to extend in a direction from the edge portion of first opening 3a toward a center 3aa of first opening 3a. First protrusion 31 is embedded in conductor layer 4. First opening 3a has a first opening width W1 in the cross section shown in FIG. 1, i.e., the first cross section passing through first protrusion 31 and center 3aa of the first opening and taken along the thickness direction of base 2. Second opening 3b has a second opening width W2 in the first cross section shown in FIG. 1. Second opening width W2 is a width of second opening 3b in the cross section taken along the thickness direction of base 2 and passing through a center 3ba in second opening 3b. In printed wiring board 1 shown in FIG. 1, first opening width W1 is smaller than second opening width W2. First opening width W1 and second opening width W2 are 10 μm to 150 μm, for example. When each of first opening width W1 and second opening width W2 is less than 10 μm, the electrical resistance of conductor layer 4 in through hole 3 increases. On the other hand, if each of first opening width W1 and second opening width W2 is more than 150 μm, there is a possibility that first opening width W1 and second opening width W2 may each become a factor of hindering space saving of the circuit formed on printed wiring board 1. Each of first opening width W1 and second opening width W2 is preferably 15 μm to 100 μm. Each of first opening width W1 and second opening width W2 is more preferably 20 μm to 75 μm.

As shown in FIG. 2, in printed wiring board 1, a protrusion length W3 of first protrusion 31 in the first radial direction toward center 3aa of first opening 3a from first protrusion 31 is 0.1 μm to 5 μm. Protrusion length W3 of first protrusion 31 may be 0.2 μm to 3 μm, 0.3 μm to 1.0 μm, or 0.4 μm 0.8 μm. Protrusion length W3 of first protrusion 31 is 0.1% to 10% of first opening width W1. Protrusion length W3 of first protrusion 31 may be 0.2% to 8%, 0.3% to 5%, or 0.5% to 3% of first opening width W1.

First conductor layer 21 included in first protrusion 31 extends in a direction along first surface 2a as shown in FIG. 2. In first protrusion 31, first conductor layer 21 may have a portion peeled off from base film 20 on the tip side of first protrusion 31. The peeled portion may have a form in which base film 20 and first conductor layer 21 are branched. Alternatively, the peeled portion may have a form in which the tip is not branched and only first conductor layer 21 is included at the tip of first protrusion 31 because the protrusion length of base film 20 is different from that of first conductor layer 21. The peeled portion may extend in a direction different from the direction in which base film 20 extends in first protrusion 31. In first protrusion 31, the position of the tip of first conductor layer 21 may be close to center 3aa of first opening 3a with respect to the position of the tip of base film 20.

First protrusion 31 may have any shape as long as it protrudes from the edge portion of first opening 3a. For example, first protrusion 31 may have a sheet-like or plate-like shape. First protrusion 31 may have a thickness of 0.1 μm or less. In the cross section shown in FIGS. 1 and 2, first protrusion 31 may have one or more bends. For example, the cross section may have a bent portion so that the tip portion of first protrusion 31 extends downward. The thickness of first protrusion 31 may become thinner as the distance from the edge portion of first opening 3a increases. Alternatively, in first protrusion 31, the second thickness at a position away from the first position when viewed from the edge portion of first opening 3a may be thicker than the first thickness at the first position relatively close to the edge portion of first opening 3a.

Conductor layer 4 includes an underlying conductor layer 4a extending from the inside of through hole 3 to the first surface or the second surface of base 2 and an upper-layer conductor layer 4b disposed on underlying conductor layer 4a. For example, an electroless plating layer can be used as underlying conductor layer 4a. An electroplated layer can be used as upper-layer conductor layer 4b. The material of underlying conductor layer 4a and upper-layer conductor layer 4b may be the same material or different materials. As the material, any metal can be used, and for example, copper or a copper alloy can be used.

<Method of Manufacturing Printed Wiring Board>

FIGS. 3 to 6 are cross-sectional schematic views for explaining a method of manufacturing printed wiring board 1 shown in FIG. 1. Hereinafter, a method of manufacturing printed wiring board 1 shown in FIG. 1 will be described.

As shown in FIG. 3, first, a step (S1) of preparing base 2 is carried out. As described above, base 2 is a stacking body of base film 20, first conductor layer 21, and second conductor layer 22. First conductor layer 21 may include, for example, a first layer containing nickel and chromium formed on the back surface of base film 20 and a second layer stacked on the first layer. As the second layer, for example, a metal layer such as copper can be used. The metal layer constituting the second layer is formed by, for example, sputtering.

Next, as shown in FIG. 4, a step (S2) of forming through hole 3 in base 2 is performed. In this step (S2), through hole 3 is formed by removing a part of base 2. As a method of forming through hole 3, an arbitrary method can be adopted, and for example, as shown by an arrow, a part of base 2 may be removed by laser beam irradiation. At this time, a part of base 2 may be left in the edge portion of first opening 3a of through hole 3 by adjusting irradiation conditions such as the output of the laser beam. First protrusion 31 may be formed by the remaining part of base 2.

Alternatively, through hole 3 and first protrusion 31 may be formed using a chemical solution or the like. For example, base 2 may have a multilayer structure including a first surface layer constituting first surface 2a, a second surface layer constituting second surface 2b, and an intermediate layer disposed between the first surface layer and the second surface layer. The first surface layer, the second surface layer and the intermediate layer may be made of different materials. After through hole 3 is formed in base 2 by an arbitrary method, a chemical solution that selectively dissolves the intermediate layer and the second surface layer may be supplied to the inside of through hole 3 with respect to the first surface layer to remove a part of the intermediate layer and the second surface layer. As a result, a part of the first surface layer protrudes from the edge portion of first opening 3a of through hole 3 to form first protrusion 31.

Next, as shown in FIG. 5, a step (S3) of forming underlying conductor layer 4a on the front surface of base 2 in which through hole 3 is formed is performed. In this step (S3), underlying conductor layer 4a is formed so as to cover the inside of through hole 3, first protrusion 31, first surface 2a, and second surface 2b. As a method of forming underlying conductor layer 4a, an arbitrary method can be adopted, and for example, an electroless plating method can be used.

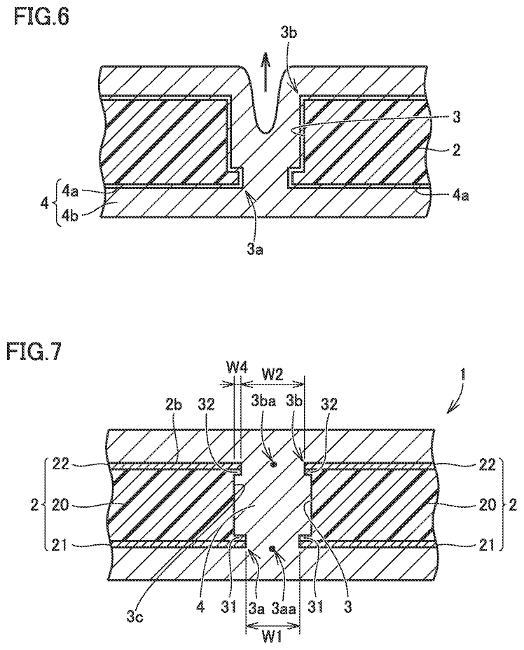

Next, as shown in FIG. 6, a step (S4) of forming upper-layer conductor layer 4b is performed. In this step (S4), upper-layer conductor layer 4b is formed on underlying conductor layer 4a. As a method of forming upper-layer conductor layer 4b, an arbitrary method can be adopted, and for example, an electroplating method can be used. At this time, as shown in FIG. 1, since first protrusion 31 is formed, first opening width W1 is narrower than second opening width W2 in through hole 3. Therefore, as shown in FIG. 6, through hole 3 is first closed by upper-layer conductor layer 4b on first opening 3a side. Thereafter, upper-layer conductor layer 4b is formed from first opening 3a side toward second opening 3b side. As a result, the inside of through hole 3 is filled with upper-layer conductor layer 4b, and the occurrence of voids can be suppressed. When upper-layer conductor layer 4b is sufficiently formed in this manner, printed wiring board 1 shown in FIG. 1 can be obtained.

<Effect>

Printed wiring board 1 according to the present embodiment includes base 2 and conductor layer 4. Base 2 includes first surface 2a and second surface 2b positioned opposite to first surface 2a. Through hole 3 reaching second surface 2b from first surface 2a is formed in base 2. First opening 3a being an open end of through hole 3 is formed in first surface 2a of base 2. Second opening 3b being an open end of through hole 3 is formed in second surface 2b of base 2. Conductor layer 4 is disposed at least inside through hole 3. Base 2 includes first protrusion 31. First protrusion 31 protrudes from an edge portion of first opening 3a. First opening 3a has first opening width W1 in the first cross section passing through first protrusion 31 and center 3aa of the first opening and taken along the thickness direction of base 2. Second opening 3b has second opening width W2 in the first cross section. First opening width W1 is smaller than second opening width W2.

In this case, since first protrusion 31 is formed at the edge portion of first opening 3a, first opening width W1 can be made smaller than second opening width W2 without largely changing the width of through hole 3 at the central portion in the extending direction. Therefore, when conductor layer 4 is formed inside through hole 3, conductor layer 4 can be formed so as to close through hole 3 on first opening 3a side. Thereafter, conductor layer 4 may be formed in through hole 3 from first opening 3a side to second opening 3b side. Therefore, it is possible to suppress the occurrence of voids by closing the first opening 3a side and the second opening 3b side before the inside of through hole 3 is filled with conductor layer 4.

Further, since first opening width W1 is adjusted by forming first protrusion 31, there is no need for a structure in which inner wall 3c itself of through hole 3 is inclined with respect to first surface 2a as in the case where inner wall 3c of through hole 3 is inclined to make first opening width W1 narrower than second opening width W2. Therefore, the problem that second opening width W2 becomes excessively larger than first opening width W1 due to the inclination of inner wall 3c of through hole 3 with respect to first surface 2a does not occur. Therefore, by making the width (second opening width W2) of second opening 3b on second surface 2b smaller than that in the related art, the region occupied by through hole 3 can be made smaller than that in the related art. As a result, it is possible to realize printed wiring board 1 in which through holes 3 are miniaturized while suppressing the occurrence of voids.

In printed wiring board 1, first protrusion 31 includes first conductor layer 21 having a material differing from the material of conductor layer 4. In this case, since first protrusion 31 can have conductivity, conductor layer 4 can be easily formed on the surface of first protrusion 31 using the electroplating method.

In printed wiring board 1, first conductor layer 21 may extend to a region adjacent to first opening 3a at the first surface of base 2. In this case, conductor layer 4 can be easily formed on first surface 2a of base 2 using the electroplating method.

In printed wiring board 1, a material of first conductor layer 21 may include nickel (Ni) or chromium (Cr). The material of conductor layer 4 may include copper (Cu), for example. In this case, first conductor layer 21 can be used as an underlying material for forming conductor layer 4. Therefore, conductor layer 4 can be easily formed so as to cover first protrusion 31.

In printed wiring board 1, first protrusion 31 may extend in a direction along first surface 2a. In this case, first opening width W1 can be reliably reduced by first protrusion 31.

In printed wiring board 1, protrusion length W3 of the first protrusion in a first radial direction from first protrusion 31 toward center 3aa of first opening 3a may be 0.1 μm to 5 μm. In printed wiring board 1, protrusion length W3 of first protrusion 31 may be 0.1% to 10% of first opening width W1. In this case, when conductor layer 4 is formed inside through hole 3, first opening 3a side can be closed by conductor layer 4 before second opening 3b side. Therefore, the occurrence of voids in conductor layer 4 inside through hole 3 can be suppressed.

<Modification>

FIG. 7 is a partial cross-sectional schematic diagram showing a first modification of printed wiring board 1 shown in FIG. 1. Printed wiring board 1 shown in FIG. 7 basically has the same configuration as printed wiring board 1 shown in FIGS. 1 and 2, but the structure of through hole 3 is different from that of printed wiring board 1 shown in FIGS. 1 and 2. Specifically, in printed wiring board 1 shown in FIG. 7, base 2 includes a second protrusion 32 protruding from the edge portion of second opening 3b. Here, the edge portion of second opening 3b is a portion of base 2 that surrounds an annular line from the outer peripheral side and is adjacent to the annular line, when the annular line is assumed as a line at which second surface 2b intersects a virtual plane obtained by extending inner wall 3c toward second surface 2b in second opening 3b. Second protrusion 32 includes second conductor layer 22 having a material differing from the material of conductor layer 4. A width (second opening width W2) of second opening 3b in the second cross section passing through second protrusion 32 and center 3ba of second opening 3b is greater than first opening width W1. That is, the second cross section shown in FIG. 7 is substantially the same cross section as the first cross section shown in FIG. 1. Second protrusion 32 extends in a direction along second surface 2b. Second protrusion 32 is formed to extend in a direction from the edge portion of second opening 3b toward center 3ba of second opening 3b. The shape of second protrusion 32 may be basically the same as the shape of first protrusion 31. Both first protrusion 31 and second protrusion 32 may be embedded in conductor layer 4.

Also in this case, since conductor layer 4 can be formed from first opening 3a side, the occurrence of voids inside through hole 3 can be suppressed as in printed wiring board 1 shown in FIGS. 1 and 2.

As shown in FIG. 7, second conductor layer 22 extends to a region adjacent to second opening 3b on second surface 2b of base 2. In FIG. 7, second conductor layer 22 is formed to cover the entire second surface 2b of base 2. In this case, second conductor layer 22 can be used as an underlying material for conductor layer 4. As a result, conductor layer 4 can be easily formed up to second surface 2b of base 2 using, for example, an electroplating method.

In printed wiring board 1, as described above, the material of second conductor layer 22 may include nickel (Ni) or chromium (Cr). In this case, second conductor layer 22 can be used as an underlying material for forming conductor layer 4. Therefore, conductor layer 4 can be easily formed so as to cover second protrusion 32.

In printed wiring board 1, a protrusion length W4 of second protrusion 32 in a second radial direction from second protrusion 32 toward center 3ba of second opening 3b may be 0.1 μm to 5 μm. Protrusion length W4 of second protrusion 32 may be 0.2 μm to 3 μm, 0.3 μm to 1.0 μm, or 0.4 μm to 0.8 μm. Also, protrusion length W4 of second protrusion 32 may be 0.1% to 10% of second opening width W2. Protrusion length W4 of second protrusion 32 may be 0.2% to 8%, 0.3% to 5%, or 0.5% to 3% of second opening width W2. In this case, conductor layer 4 can be easily formed so as to cover the periphery of second protrusion 32.

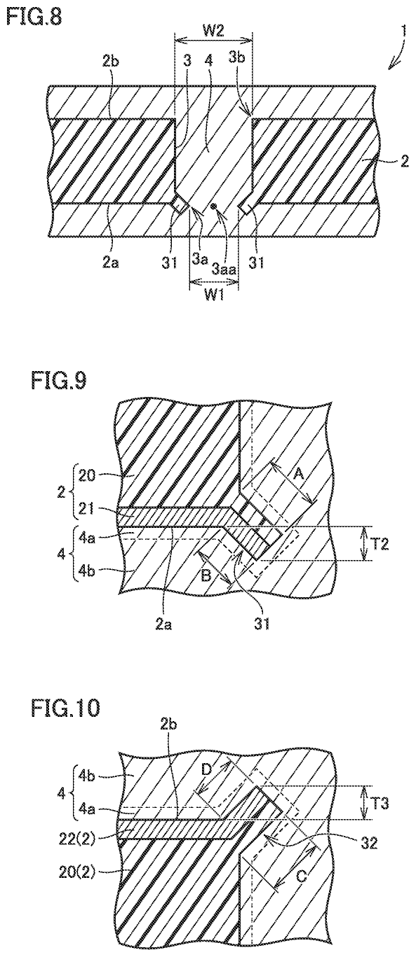

FIG. 8 is a partial cross-sectional schematic diagram showing a second modification of the printed wiring board shown in FIG. 1. FIG. 9 is a partially enlarged cross-sectional schematic view of the printed wiring board shown in FIG. 8. Printed wiring board 1 shown in FIGS. 8 and 9 has basically the same configuration as printed wiring board 1 shown in FIGS. 1 and 2, but the structure of through hole 3 is different from that of printed wiring board 1 shown in FIGS. 1 and 2. Specifically, in printed wiring board 1 shown in FIGS. 8 and 9, first protrusion 31 extends in a direction intersecting first surface 2a. First protrusion 31 extends away from first surface 2a in a direction perpendicular to first surface 2a as first protrusion 31 approaches center 3aa of first opening 3a from the edge portion of first opening 3a. Also in this case, since first protrusion 31 protrudes from the edge portion of first opening 3a, first opening width W1 can be reduced by first protrusion 31.

When first protrusion 31 extends in a direction intersecting first surface 2a as shown in FIGS. 8 and 9, the protrusion length of first protrusion 31 can be an average value of length A and length B shown in FIG. 9. In the cross section shown in FIG. 9, length A is the protrusion length from the inner wall of through hole 3, the length being of a member constituting the first surface portion facing the inside of through hole 3 in first protrusion 31 (the part of base film 20 constituting first protrusion 31 in FIG. 9). That is, as shown in FIG. 9, length A is a distance from a connection portion between the inner wall of through hole 3 and first protrusion 31 to a portion (tip portion) farthest from the connection portion in the member constituting the first surface portion of first protrusion 31. In the cross section shown in FIG. 9, length B is the protrusion length from first surface 2a, the length being of a member constituting the second surface portion positioned opposite to the first surface portion in first protrusion 31 (a part of first conductor layer 21 constituting first protrusion 31 in FIG. 9). That is, as shown in FIG. 9, length B is a distance from a connection portion between the flat region of first surface 2a and first protrusion 31 to a portion (tip portion) farthest from the connection portion in the member constituting the second surface portion of first protrusion 31. The above-described protrusion length of first protrusion 31 may be applied to a case in which first protrusion 31 has a bent portion. When first conductor layer 21 has a portion peeled off from base film 20 on the tip side of first protrusion 31, the protrusion length of first protrusion 31 is the average value of the distance from the connection portion between the inner wall of through hole 3 and first protrusion 31 to the portion (tip portion) of first protrusion 31 farthest from the connection portion and the distance from the connection portion between the flat region of first surface 2a and first protrusion 31 to the portion (tip portion) of first protrusion 31 farthest from the connection portion.

In printed wiring board 1, a protrusion height T2 of first protrusion 31 in a direction perpendicular to first surface 2a is 0.01 μm to 1 μm. Protrusion height T2 of first protrusion 31 may be 0.02 μm to 0.8 μm, 0.03 μm to 0.7 μm, or 0.04 μm to 0.6 μm. Protrusion height T2 of first protrusion 31 is 0.01% to 10% of a thickness T1 of base 2 (see FIG. 1). Protrusion height T2 of first protrusion 31 may be 0.02% to 8%, 0.03% to 5%, or 0.05% to 3% of thickness T1 of base 2. In this case, conductor layer 4 can be easily formed so as to cover first protrusion 31.

FIG. 10 is a partial cross-sectional schematic view showing a third modification of the printed wiring board shown in FIG. 1. Printed wiring board 1 shown in FIG. 10 basically has the same configuration as printed wiring board 1 shown in FIG. 7, but the structure of through hole 3 is different from that of printed wiring board 1 shown in FIG. 7. Specifically, in printed wiring board 1 shown in FIG. 10, second protrusion 32 extends in a direction intersecting second surface 2b. Second protrusion 32 extends away from second surface 2b in a direction perpendicular to second surface 2b as second protrusion 32 approaches center 3ba of second opening 3b from the edge portion of second opening 3b.

As shown in FIG. 10, when second protrusion 32 extends in a direction intersecting second surface 2b, the protrusion length of second protrusion 32 can be an average value of length C and length D shown in FIG. 10. In the cross section shown in FIG. 10, length C is the protrusion length from the inner wall of through hole 3, the length being of a member constituting the third surface portion facing the inside of through hole 3 in second protrusion 32 (a part of base film 20 constituting second protrusion 32 in FIG. 10). That is, as shown in FIG. 10, length C is a distance from a connection portion between the inner wall of through hole 3 and second protrusion 32 to a portion (tip portion) farthest from the connection portion in the member constituting the third surface portion of second protrusion 32. In the cross section shown in FIG. 10, length D is the protrusion length from second surface 2b, the length being of a member constituting the fourth surface portion positioned opposite to the third surface portion in second protrusion 32 (a part of second conductor layer 22 constituting second protrusion 32 in FIG. 10). That is, as shown in FIG. 10, length D is a distance from a connection portion between the flat region of second surface 2b and second protrusion 32 to a portion (tip portion) farthest from the connection portion in the member constituting the fourth surface portion of second protrusion 32. The protrusion length of second protrusion 32 described above may be applied to a case in which second protrusion 32 has a bent portion. When second conductor layer 22 has a portion peeled from base film 20 on the tip side of second protrusion 32, the protrusion length of second protrusion 32 is the average value of the distance from the connection portion between the inner wall of through hole 3 and second protrusion 32 to the portion (tip portion) of second protrusion 32 farthest from the connection portion and the distance from the connection portion between the flat region of second surface 2b and second protrusion 32 to the portion (tip portion) of second protrusion 32 farthest from the connection.

A protrusion height T3 of second protrusion 32 in a direction perpendicular to second surface 2b is 0.01 μm to 1 μm. Protrusion height T3 of second protrusion 32 may be 0.02 μm to 0.8 μm, 0.03 μm to 0.7 μm, or 0.04 μm to 0.6 μm. In printed wiring board 1, protrusion height T3 of second protrusion 32 is 0.01% to 10%/o of thickness T1 of base 2 (see FIG. 1). Protrusion height T3 of second protrusion 32 may be 0.02% to 8%, 0.03% to 5%, or 0.05% to 3% of thickness T1 of base 2. In this case, conductor layer 4 can be easily formed so as to cover second protrusion 32.

### Second Embodiment

### <Configuration and Operational Effects of Printed Wiring Board>

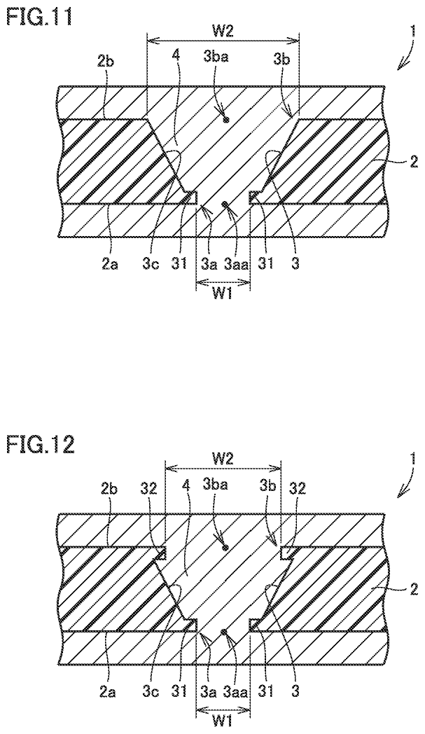

FIG. 11 is a partial cross-sectional schematic view of a printed wiring board according to a second embodiment. Printed wiring board 1 shown in FIG. 11 basically has the same configuration as that of printed wiring board 1 shown in FIGS. 1 and 2, but the structure of through hole 3 is different from that of printed wiring board 1 shown in FIGS. 1 and 2. Specifically, in printed wiring board 1 shown in FIG. 11, inner wall 3c of through hole 3 is inclined with respect to first surface 2a. That is, in through hole 3, inner wall 3c of through hole 3 is inclined with respect to first surface 2a so that the width of through hole 3 increases from first opening 3a toward second opening 3b. In this case, conductor layer 4 can be reliably formed from first opening 3a side, so that the occurrence of voids inside through hole 3 can be further suppressed. Since first opening width W1 is adjusted by first protrusion 31, the effect of suppressing the occurrence of voids can be obtained even if the inclination angle of inner wall 3c of through hole 3 is minimized.

<Modification>

FIG. 12 is a partial cross-sectional schematic diagram showing a first modification of the printed wiring board shown in FIG. 11. Printed wiring board 1 shown in FIG. 12 basically has the same configuration as printed wiring board 1 shown in FIG. 11, but the structure of through hole 3 is different from that of printed wiring board 1 shown in FIG. 11. Specifically, in printed wiring board 1 shown in FIG. 12, base 2 includes second protrusion 32 protruding from the edge portion of second opening 3b. The configuration of second protrusion 32 in printed wiring board 1 shown in FIG. 12 is the same as the configuration of second protrusion 32 in printed wiring board 1 shown in FIG. 7.

As shown in FIG. 12, the width (second opening width W2) of second opening 3b in the second cross section taken along the thickness direction of base 2 and passing through second protrusion 32 and center 3ba of second opening 3b is greater than first opening width W1. That is, the second cross section shown in FIG. 12 is substantially the same cross section as the first cross section shown in FIG. 11. Second protrusion 32 extends in a direction along second surface 2b. Second protrusion 32 is formed to extend in a direction from the edge portion of second opening 3b toward center 3ba of second opening 3b. The shape of second protrusion 32 may be basically the same as the shape of first protrusion 31. First protrusion 31 and second protrusion 32 are both embedded in conductor layer 4. Also in this case, as in printed wiring board 1 shown in FIG. 11, the occurrence of voids inside through hole 3 can be suppressed.

### Examples

In order to confirm the effect of the printed wiring board according to the present disclosure, the following experiment was conducted.

<Sample>

Samples 1 to 4 were prepared. Samples 1 to 4 are printed wiring boards in each of which 100 through holes are formed. The structures of the through holes of the samples 1, 2 and 3 are basically the same as the structure of through hole 3 shown in FIGS. 1 and 2.

The sample 1, the sample 2, and the sample 3 are formed so that protrusion length W3 of first protrusion 31 is different from each other. That is, protrusion length W3 of first protrusion 31 in the sample 1 is 0.05 μm. Protrusion length W3 of first protrusion 31 in the sample 2 is 0.1 μm. Protrusion length W3 of first protrusion 31 in the sample 3 is 0.5 μm.

The first protrusion shown in FIG. 1 is not formed in the through hole of the sample 4. In the through hole of the sample 4, the second opening width on second surface 2b side is wider than the first opening width on first surface 2a side. In the through hole of the sample 4, the inner wall is inclined with respect to first surface 2a.

Note that the conditions other than the above-described conditions regarding the through hole are the same among the samples 1 to 4. Specifically, as shown in FIG. 3, the base has a stacked structure of a base film, a first conductor layer and a second conductor layer. The material of the base film is polyimide. The thickness of the base film is 75 μm. The material of each of the first conductor layer and the second conductor layer is a nickel-chromium alloy. The thicknesses of each of the first conductor layer and the second conductor layer are 10 nm. The through holes are formed so as to be arranged in one row at intervals of 1 mm. As a method of forming the through hole, laser processing was used.

<Test Method>

### Conductor Layer Formation:

For each of the above-described samples 1 to 4, conductor layer 4 was formed so as to fill the through hole by performing the steps shown in FIGS. 5 and 6. Specifically, electroless copper plating was performed to form a copper plating layer as underlying conductor layer 4a shown in FIG. 5. The thickness of the copper plating layer was 0.1 μm. Thereafter, copper electroplating was performed to form a copper plating layer as upper-layer conductor layer 4b shown in FIG. 6. The current density in the electrolytic copper-plating was 2 A/dm². The plating time was set to 120 minutes.

Void Measurement:

For each of Sample 1 to Sample 4, cross sections of 100 through holes were observed to confirm the presence or absence of voids. Specifically, each sample was subjected to cross section processing using a microtome. Thereafter, the presence or absence of voids was confirmed by microscopic observation at a magnification of 500 times. For each sample, the proportion of through holes in which voids were generated among 100 through holes was calculated as the void occurrence rate.

<Results>

The results are shown in Table 1.

TABLE 1

| | | Protrusion | | | Void |
|---|---|---|---|---|---|
| | Presence | Length of | First | Second | Occur- |
| | or Absence | First | Opening | Opening | rence |
| | of First | Protrusion | Width | Width | Rate |
| | Protrusion | (μm) | (μm) | (μm) | (%) |
| Sample 1 | Present | 0.05 | 50 | 60 | 2 |
| Sample 2 | Present | 0.1 | 50 | 60 | 0 |
| Sample 3 | Present | 0.5 | 50 | 60 | 0 |
| Sample 4 | Absent | — | 50 | 60 | 5 |

Table 1 shows the presence or absence of the first protrusion, the protrusion length of the first protrusion, first opening width W1, second opening width W2, and the void occurrence rate for each sample. The protrusion length of the first protrusion, the first opening width, and the second opening width are average values of data of 100 through holes in each sample. As shown in Table 1, in the sample 4 as the comparative example, since the first protrusion is not formed, the void occurrence rate is larger than that of the other samples. On the other hand, in Samples 1 to 3 as examples, the void occurrence rate is smaller than that of Sample 4. Further, the void occurrence rates of Sample 2 and Sample 3 are smaller than that of Sample 1.

As described above, the effect of protrusion in the through hole of the printed wiring board was confirmed. It should be understood that the embodiments disclosed herein are illustrative in all respects and are not restrictive. The scope of the present invention is defined not by the above-described embodiments but by the claims, and is intended to include meanings equivalent to the claims and all modifications within the scope.

### REFERENCE SIGNS LIST

1 printed wiring board, 2 base, 2a first surface, 2b second surface, 3 through hole, 3a first opening, 3aa, 3ba center, 3b second opening, 3c inner wall, 4 conductor layer, 4a underlying conductor layer, 4b upper-layer conductor layer, 20 base film, 21 first conductor layer, 22 second conductor layer, 31 first protrusion, 32 second protrusion, T1 thickness, T2 protrusion height, W1 first opening width, W2 second opening width, W3 length, W3, W4 protrusion length

1. A printed wiring board comprising:
a base having a first surface and a second surface positioned opposite to the first surface,
wherein a through hole reaching the second surface from the first surface is formed in the base,
wherein a first opening being an open end of the through hole is formed in the first surface of the base,
wherein a second opening being an open end of the through hole is formed in the second surface of the base,
the printed wiring board further comprising a conductor layer disposed at least inside the through hole,
wherein the base includes
a first protrusion protruding from an edge portion of the first opening,
wherein the first opening has a first opening width in a first cross section passing through the first protrusion and a center of the first opening and taken along a thickness direction of the base,
wherein the second opening has a second opening width in the first cross section, and
wherein the first opening width is smaller than the second opening width.

2. The printed wiring board according to claim 1,
wherein, in the first cross section, an inner wall of the through hole is inclined with respect to the first surface such that a width of the through hole increases toward the second opening from the first opening.

3. The printed wiring board according to claim 1,
wherein the first protrusion includes a first conductor layer including a material differing from a material of the conductor layer.

4. The printed wiring board according to claim 3,
wherein the first conductor layer extends to a region adjacent to the first opening at the first surface of the base.

5. The printed wiring board according to claim 3,
wherein the material of the first conductor layer includes nickel or chromium.

6. The printed wiring board according to claim 3,
wherein the base includes a second protrusion protruding from an edge portion of the second opening, and
wherein the second protrusion includes a second conductor layer including a material differing from the material of the conductor layer.

7. The printed wiring board according to claim 6,
wherein the second conductor layer extends to a region adjacent to the second opening at the second surface of the base.

8. The printed wiring board according to claim 6,
wherein the material of the second conductor layer includes nickel or chromium.

9. The printed wiring board according to claim 1,
wherein the first protrusion extends in a direction along the first surface.

10. The printed wiring board according to claim 1,
wherein the first protrusion extends in a direction crossing the first surface.

11. The printed wiring board according to claim 1,
wherein a protrusion length of the first protrusion in a first radial direction toward the center of the first opening from the first protrusion is 0.1 μm to 5 μm.

12. The printed wiring board according to claim 11,
wherein the protrusion length of the first protrusion is 0.1% to 10% of the first opening width.

13. The printed wiring board according to claim 10,
wherein a protrusion height of the first protrusion in a direction perpendicular to the first surface is 0.01 μm to 1 μm.

14. The printed wiring board according to claim 13,
wherein the protrusion height of the first protrusion is 0.01% to 10% of a thickness of the base.
